(19) United States
(12) Patent Application Publication
(10) Pub. No.: US 2003/0217019 A1
(43) Pub. Date: Nov. 20, 2003

(54) System and method for increasing yield from performance contracts

(76) Inventor: Gary Allen Weiss, Wilson, WY (US)

Correspondence Address: Michael D. Bednarek, Shaw Pittman LLP, 1650 Tysons Boulevard, McLean, VA, 22102, US

(21) Appl. No.: 10/405,498

(22) Filed: Apr. 3, 2003

Related U.S. Application Data
(60) Provisional application No. 60/369,598, filed on Apr. 4, 2002.

(51) Int. Cl. G06F 17/60; G06G 7/00; G06F 17/00; G01R 11/56; G01R 21/133

(52) U.S. Cl. 705/412; 705/37; 705/2

(57) ABSTRACT

A method for increasing the yield from performance contracts having intrinsic volatility. The intrinsic volatility involves elements affected by changes that are controllable. The method involves converting a future upside potential value of the intrinsic volatility into a current monetary benefit, and using the current monetary benefit to hedge against future extrinsic volatility that could diminish the future upside potential value. The future extrinsic volatility involves elements affected by changes that are hedgeable. A corresponding system is also disclosed.

This application claims the benefit of U.S. Provisional Application No. 60/369,598, filed Apr. 4, 2002, which is herein incorporated by reference in its entirety.

### BACKGROUND

1. Field of the Invention

The present invention relates generally to Real Options, a subset of financial derivatives. More particularly, the present invention relates to using Real Options to create value from the future volatility of real energy assets, within the context of performance contracting (PC).

2. Background of the Invention

Traditionally, uncertainties with respect to future energy costs and the future energy consumption of these assets have been a deterrent to harvesting their maximum energy savings potential. Overcoming this obstacle could result in a higher potential energy savings yield from performance contracting (PC) projects. This opportunity is especially important for countries outside of the U.S., where there is high volatility and guaranteeing future energy savings may be considered too risky. Considering that approximately $30 billion is spent annually in the U.S. alone on demand-side performance contracting work, improving the energy savings yield of the PC process worldwide would be a significant breakthrough.

By way of background, the energy asset infrastructure of an organization is defined as those assets that provide a proper environment in which to work, or convert energy into a different form that supports a process. In order to understand the fundamental risks involved with the management of the energy asset infrastructure, it is helpful to express these elements in the form of an equation:

$$\begin{matrix}Total Cost ( TC ) = {Volume}_{energy} \times {Rate}_{energy} + {Volume}_{R M Laber} \times \\ {Rate}_{R M Laber} + Administration + Energy Rate Volatility + \\ Energy Volume Volatility + Laber Cost Volatility + \\ Asset Efficiency Volatility\end{matrix}$$

In this equation, the Total Cost elements are defined as follows:

| | |
|---|---|
| Volume_{energy} | Volume of energy used by the energy asset infrastructure; |
| Rate_{energy} | Rate paid for each unit of energy used by the energy |
| | asset infrastructure; |
| Volume_{RM Labor} | Amount of physical work required to operate, repair, and |
| | maintain the energy asset infrastructure; |
| Rate_{RM Labor} | Rate paid for each unit of physical work required to |
| | operate, repair, and maintain the energy asset |
| | infrastructure; |
| Administration | Amount of money required to administer the activities |
| | surrounding the energy asset infrastructure; |
| Energy Rate | Risk associated with Rate_{energy} including risk associated |
| Volatility | with traded markets as well as regulatory driven tariff |
| | changes; |
| Energy Volume | Risk associated with Volume_{energy}, including risk |
| Volatility | associated with weather, behavior changes (both the |
| | customer's and O&M personnel), and business drivers |
| | such as production and occupancy; |
| Labor Cost | Risk associated with the labor cost component of |
| Volatility | Rate _{RM}; and |
| Asset | Risk associated with changes in asset energy efficiency, |
| Efficiency | as it relates to Volatility design, installation, and |
| | operation of the energy asset infrastructure. |

This framework is helpful for understanding the effects of volatility upon the traditional PC process. However, because the costs and volatilities associated with Operation & Maintenance and Administration are de minimus when compared to energy-related costs, they are not contained within the cost equations herein.

The Traditional Performance Contracting Method:

Energy Service Companies (ESCOs) routinely provide energy efficiency services for the customers' energy asset infrastructure. Many ESCOs are involved in performance-based work, whereby their compensation is tied to the amount of energy actually saved by the customer.

In the North American Performance Contracting Model, most ESCO performance-based projects are financed entirely with debt, which goes on the balance sheet of the customer. As an example of this model, FIG. 1A illustrates the typical parties to a traditional performance contracting transaction and the interaction between the parties. The customer (or owner) 100 borrows money 102 from a Third Party Financier (TPF) 104 and has the duty 106 to repay it, not the ESCO 108. However, the ESCO 108 will guarantee 110 that savings meet or exceed the annual payments to cover all project costs—usually over a contract term of 10 years or more. If energy savings do not materialize, the ESCO 108 pays the difference, not the customer 100.

A traditional performance contracting method involves the phases listed below. FIG. 1B illustrates the typical timelines associated with each of these phases.

I. Request for Qualifications/Proposal Phase

Issue Request for Proposals

Site visits

Proposal review and selection of finalists

ESCO selection and award

II. Audit and Project Development Phase**

ESCO prepares technical “investment grade” energy audit to evaluate costs and savings of a variety of energy-saving measures

Project development plan including a Net Present Value (NPV) financial analysis (** ESCOs usually will recoup their costs ($0.07-$0.08 per sq. ft.) for the Audit and Project Development Phase of the project should it not proceed for reasons beyond their control (e.g., inability of the customer to obtain financing, inadequate Internal Rate of Return (IRR), etc.).)

III. Construction/Implementation/Financing Phase

design services

equipment procurement and purchasing

construction management

financing capability or ability to help find financing

IV. Commissioning/Guarantee/Monitoring Phase

commissioning

continuing operations and maintenance for all improvements

staff training on routine maintenance and operation of systems

performance and cost guarantee of savings

monitoring and verification for measurement, and reporting of the performance and savings from improvements

analysis and application for Energy Star Label

monitoring and reporting of emissions reductions

maintaining long-term, high-efficiency performance of buildings

The ESCO utilizes information gleaned from the Audit and Project Development Phase of the PC Process to calculate total cost savings, or Total Return (TR), as follows:

Total Cost (TC)=Volume_{energy}×Rate_{energy}

TR=TC_{Exist}−TC_{New}

From the expected savings, the customer can calculate his Net Present Value (NPV) and Internal Rate of Return (IRR), as follows:

$$Present Value ( P V ) = TR \frac{( {( 1 + i )}^{n} - 1 )}{( {i ( 1 + i )}^{n} )} \begin{matrix}NPV = Total Installed Cost ( TIC ) - PV \\ IRR = Interest rate whereby NPV = 0\end{matrix}$$

Notably, in the U.S., ESCOs are only willing to guarantee a maximum of 80% of the estimated energy savings because of concerns with respect to future volatilities that could adversely affect their predicted savings. Outside the U.S., ESCOs are willing to guarantee only 50%-65% of the estimated energy savings because of the greater level of uncertainty.

The following example (Example 1A) demonstrates how the actual energy savings yield from the traditional PC process can be far less than the potential energy savings yield.

Example 1A:

As a result of an Investment Grade Energy Audit, an ESCO has submitted a proposal to install various energy savings projects. In the aggregate, these projects are estimated to reduce the customer's annual energy consumption by 125,000 MWh, from his current baseline energy consumption of 1,000,000 MWh.

The Total Installed Cost to install these energy efficiency projects is $2,000,000. The ESCO's stipulated gross margin to perform this work is 20%, or $400,000. In addition, the ESCO receives 100% of any monies saved beyond the customer's minimum Internal Rate of Return threshold of 15%. The ESCO is required to supplement any savings shortfalls below the minimum IRR.

Because of concerns with respect to future volatilities, the ESCO will only commit to guaranteeing savings of 100,000 MWh. Electricity presently costs $50/MWh. The term of the contract is six years. The ESCO anticipates no O&M or Administration costs savings. Therefore,

$$\begin{matrix}Total Return ( TR ) = 1 , 000 , 000 MWh \times \$50 / MWh - \\ 900 , 000 MWH \times \$50 / MWh \\ = \$ 5 , 000 , 000 per year\end{matrix}$$

Present Value (TR)=$500,000×3.784=$1,892,000

NPV=$1,892,000−$2,000,000=($108,000)→which is below the required IRR “hurdle rate.”

To salvage the deal, the ESCO reviews his Energy Audit work papers and resubmits a more modest proposal to perform a lighting retrofit at a cost of $500,000. This will save 30,000 MWh per year from his estimated current consumption of 250,000 MWh per year.

TR=30,000 MWh×$50/MWh=$150,000 per year

Present Value =$150,000×3.784=$567,600 per year

NPV=$567,600−$500,000=$67,600

Unfortunately, in the beginning of the second year of the contract, energy rates decline from $50/MWh to $40/MWh. With this knowledge, the Present Value and Net Present Value can be recalculated to:

Present Value=$150,000×0.87+$120,000×3.352×0.8696=$480,288

NPV=$480,288−$500,000=($19,712)

This is below the minimum guaranteed IRR threshold. The ESCO would therefore have had to make up this $19,712 shortfall.

Thus, Example 1A demonstrates that some seemingly promising PC projects, in actuality, do not come close to realizing their potential energy saving yield.

Disadvantages of Traditional Performance:

The traditional performance contracting process normally takes only four to five months from the time that an ESCO begins the Energy Audit until construction is ready to commence (see FIG. 1B). Yet, the length of a performance contract can be from five years to twenty-five years. Thus, the ESCO is forced to “put a stake in the ground” and commit (via his guaranteed savings) to one vision of an uncertain future.

Some specific factors affecting this future prediction of guaranteed savings include one or more of:

Inadequate time or methodology to establish an accurate volumetric consumption baseline;

Inability to monitor behavioral changes that could result in greater consumption of energy when new equipment is installed;

Inability to monitor actions that could decrease asset efficiency, such as poor maintenance; and

Volatility in future energy rates, currency exchange rates, interest rates, etc.

As illustrated in Example 1A, above, the ESCO deals with these future risks simply by shaving off a portion of the anticipated guaranteed savings to create a “cushion” as a hedge against this uncertainty.

Some disadvantages of this existing process include one or more of the following:

The performance contracting process is binary: A Proposal is either accepted or rejected. There is no ability to defer the decision until uncertainties become better quantified. When a proposal is rejected, all costs expended, such as for the Energy Audit, become non-recoverable.

Because the ESCO simply inserts a “fudge factor” to deal with future volatility, the process is sub-optimized: Deserving potential energy savings projects may get “scrubbed” because they do not meet the customer's IRR. Other projects are given the “green light,” but ultimately fail to meet financial expectations.

The performance contracting process is further negatively affected because it reinforces a mind-set where only the most straightforward least-risk types of projects are submitted for consideration. An example of this type of project would be a lighting retrofit (replacing less efficient lighting fixtures with more efficient lighting fixtures). Other types of projects that could yield greater savings but involve a higher degree of future uncertainty are less likely to be submitted for consideration.

For countries that operate in an environment of high future volatility, the issues above become exacerbated to the point that the performance contracting process may cease to be viable.

The following printed publications provide further background on the present invention, and are incorporated herein by reference in their entireties: Performance Contracting—Expanding Horizons by Shirley J. Hansen Ph.D.; Options, Futures, & Other Derivatives by John C. Hull; Economic Analysis by Normal Barish; Investment Opportunities as Real Options: Getting Started on the Numbers by Timothy Luehrman; and The International Measurement and Verification Protocol.

Thus, as demonstrated above, ESCOs have traditionally employed a simplified approach to dealing with the impact of future volatility upon their projected energy savings. As stated in Shirley Hansen's book Performance Contracting—Expanding Horizons, “[w]hat the (ESCO) Industry needs, but presently lacks, is the equivalent of the insurance industry's actuarial tables for the considered measures against specific conditions that significantly impact savings projections.”

### SUMMARY OF THE INVENTION

From a purely financial perspective, investment in an organization's energy asset infrastructure “competes” with other potential investments, such as an expansion or acquisition. All of these potential investments may involve Third Party Financing. The key “success metric” is, in every case, whether the potential investment meets the organization's threshold Internal Rate of Return (IRR).

With respect to performance contracting, the present invention identifies two aspects of future volatility that affect the threshold IRR:

Intrinsic volatility, which involves those elements directly affected by changes that are measurable, verifiable, and controllable. Typically, these changes would occur within the facility related to the performance contract. Examples of intrinsic volatility include the Energy Volume Risk, Asset Performance Risk, and Energy Baseline Uncertainty Risk.

Extrinsic volatility, which involves those risks that are hedgeable. Typically, these changes would occur outside of the facility related to the performance contract. Examples of extrinsic volatility include Energy Rate Risk, Labor Cost Risk, Interest Rate Risk, and Currency Risk.

Recognizing these effects of future volatility on threshold IRR, the present invention provides a system and method for increasing the yield from performance contracts. Specifically, the present invention provides a “Hunting License” (Real) Option that converts the future upside potential value of the PC project intrinsic volatility into a tangible current monetary benefit. This cash is used to hedge those future extrinsic risks that could possibly diminish this potential value.

In a further embodiment of the present invention, the Hunting License Option is combined with volatility insurance to create a stable “platform” for the ESCO, which optimizes specific energy asset upgrade work over time. In this manner, intrinsic volatilities can be controlled and extrinsic volatilities are hedged, thus maximizing the IRR yield.

### BRIEF DESCRIPTION OF THE DRAWINGS

FIG. 1A is a schematic diagram illustrating the parties to a traditional performance contracting transaction and the interaction between the parties.

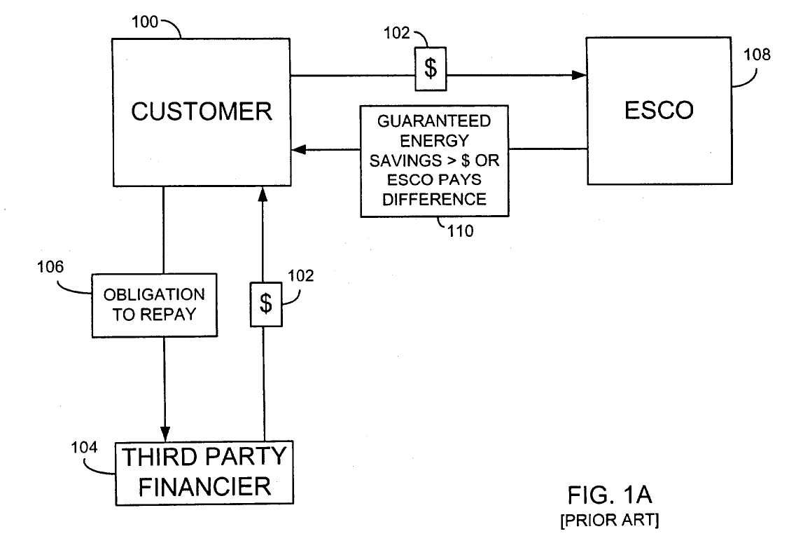

FIG. 1B is a chart outlining the typical timelines for each phase of a traditional performance contracting process.

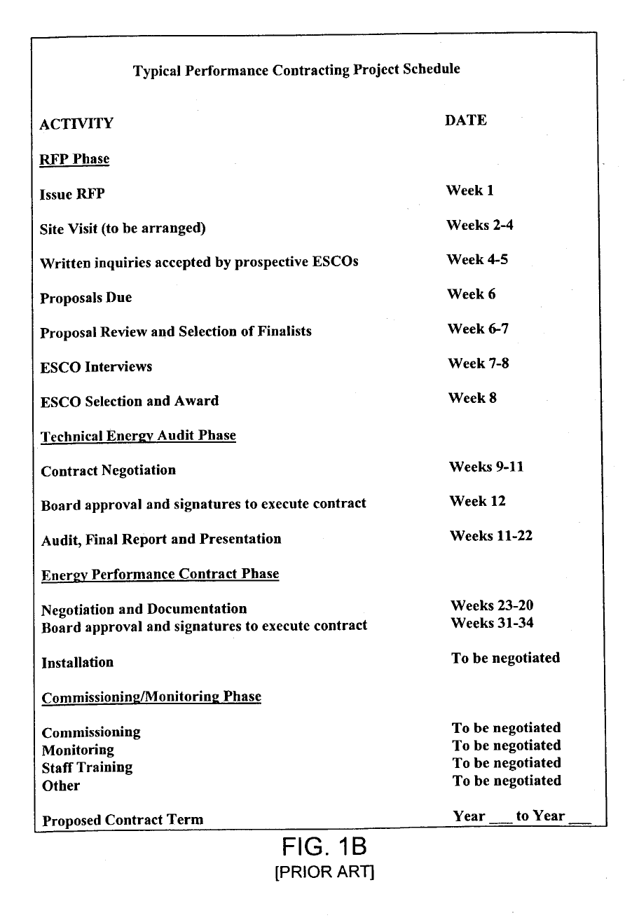

FIG. 2A is a schematic diagram illustrating an exemplary system for performance contracting, according to an embodiment of the present invention.

FIG. 2B is a flowchart describing an exemplary process for performance contracting, according to an embodiment of the present invention.

FIG. 3 is a table that lists option factors according to the European Black-Scholes pricing model.

FIG. 4 is a table that compares traditional performance contracting to the present invention, according to an embodiment of the present invention.

### DETAILED DESCRIPTION OF THE INVENTION

As described above, a performance contracting process represents a defined plan with a minimum guaranteed financial outcome. What is lacking in the prior art is a mechanism to take advantage of the serendipitous, unobvious opportunities within that process that only reveal themselves over time, yet can potentially maximize the energy savings cost benefits.

An embodiment of the present invention provides a Hunting License Option, which is a vehicle that enables the performance contracting process (or any similar process) to obtain an optimum financial outcome.

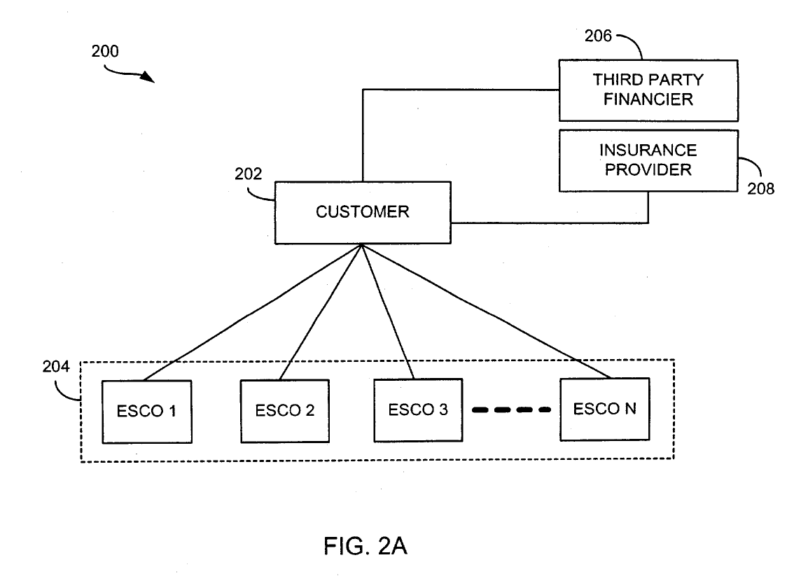

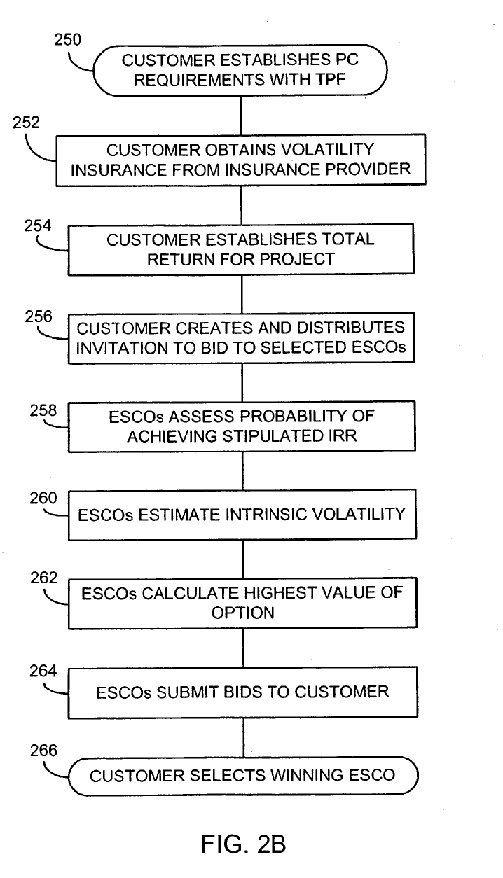

FIG. 2A illustrates an exemplary system 200 for performance contracting that takes advantage of the Hunting License Option, according to an embodiment of the present invention. As shown, system 200 includes a customer (or owner) 202 in communication with a plurality of ESCOs 204, a third party financier 206, and an insurance provider 208. Customer 202 participates with the plurality of ESCOs 204 in a bidding process for the Hunting License Option. Third party financier 206 lends money to customer 202 in return for customer 202's repaying the debt, in most cases, with interest. Insurance provider 208 provides customer 202 with volatility insurance in return for customer 202's payment of an insurance premium. Although FIG. 2A shows three ESCOs 204, as one of ordinary skill in the art would appreciate, the number of ESCOs could vary from one to many, as represented by ESCO N.

With continuing reference to system 200 of FIG. 2A, the flowchart of FIG. 2B describes an exemplary process for performance contracting, according to an embodiment of the present invention. As shown, customer 202 completes the following three steps prior to soliciting bids for a Hunting License Option:

1. Customer 202 works with third party financier 206 to establish performance contract requirement (Step 250), such as:

A “not to exceed” Total Installed Cost (TIC) of the performance contracting work;

A minimum threshold Internal Rate of Return (IRR) for the PC work;

An allowable ESCO gross margin;

The length of the Hunting License Option (T); and

The length of the performance contract.

2. Customer 202 obtains from insurance provider 208 a Volatility Insurance “binder” (Step 252) that, for the length of the performance contract, hedges against:

The stipulated energy rate going down;

Interest rates going up; and

Currency rate volatility (if applicable).

3. Customer 202 reviews the Investment Grade Energy Audit and establishes the projected volumetric energy reduction, or Total Return (TR), for the project (Step 254).

Once these pre-bid steps are successfully completed, customer 202 creates and distributes an Invitation to Bid to a select group of Certified ESCOs 204 (Step 256). Each of the invitees will submit a scaled bid for the Hunting License Option, which technically is analogous to an American Black-Scholes financial “hard” option with the following features:

The Option is exclusive to the “winning” ESCO until expiration; and

Every project identified by the ESCO that meets the threshold IRR must be approved by the customer, until the “not to exceed” TIC is reached.

Steps 1 through 3 above (corresponding to Steps 250, 252, and 254 of FIG. 2B) quantify elements required for an ESCO to submit a bid for the Hunting License Option. However, within this framework, each ESCO 204 that is a participant in the bid submission process independently assesses the following two factors:

What is the probability of achieving the stipulated IRR for the entire “not to exceed” Total Installed Cost within the Option period? (Step 258)

What is the estimated (intrinsic) volatility (σ), beyond the calculated minimum value, of all existing and upgraded energy assets? (Step 260)

The unique Knowledge Management capabilities of each respective ESCO 204, combined with an appropriate number of site inspections and review of the Energy Audit and other relevant documentation, will determine how they evaluate these two factors, and thus, calculate the highest value of the Option (Step 262).

The technical equations for calculating the Hunting License Option value are presented below:

$$\begin{matrix}NPV = TIC - PV , where PV = TR \frac{( {( 1 + i )}^{n} - 1 )}{( {i ( 1 + i )}^{n} )} or \\ TR = PV \frac{( {i ( 1 + i )}^{n} )}{( {( 1 + i )}^{n} - 1 )} \\ \frac{( {i ( 1 + i )}^{n} )}{( {( 1 + i )}^{n} - 1 )} = Capital Recovery Factor [ CR ] , thus \\ TR = PV \times [ CR ]\end{matrix}$$

Define a new element, NPV_{q}, wherein:

$${NPV}_{q} = \frac{TIC}{PV} = \frac{TIC \times [ CR ]}{TR}$$

Without considering volatility, and assuming that the energy rate will remain constant, Total Return is:

TR=[Volume_{energy}]_{Exist-New}×Rate_{energy}

However, to accurately calculate the true Total Return, the intrinsic volatilities (1±σₓ) must be included. Thus,

TR=[Volume_{energy}]_{Exist-New}×(1±σₓ)×Rate_{energy},

where

σₓ=σ_{V}×σ_{E}×σ_{baseline},

σᵥ=volumetric volatility;

σ_{E}=asset efficiency volatility; and

σ_{Baseline}=baseline energy consumption uncertainty.

At the stipulated minimum IRR, we know that NPV_{q}=1. Thus,

$$\begin{matrix}{NPV}_{q} = \frac{TIC \times [ CR ]}{{[ {Volume}_{energy} \times ( 1 + {σ}_{X} ) ]}_{Exist - New} \times {Rate}_{energy}} = 1 , and \\ {( 1 \pm {σ}_{X} )}_{Exist - New} = \frac{[ CR ] \times TIC}{{[ {Volume}_{energy} ]}_{Exist - New} \times {Rate}_{energy}} \\ = {σ}_{XExist} \pm {σ}_{XNew}\end{matrix}$$

One last element, Cumulative Volatility (CV), must be defined to calculate this Black-Scholes Option:

CV=σ_{XExist}±σ_{XNew}×\sqrt{T},

where T=the length of the Option.

Referring again to FIG. 2B, after calculating the Option, the ESCOs 204 submit their bids to customer 202 (Step 264). Customer 202 then selects the ESCO 204 with the winning bid (Step 266).

The following example (Example 1B) illustrates an exemplary implementation of the present invention.

Example 1B:

A U.S.-based customer, after reaching an agreement with his Third Party Financier, obtaining a Volatility Insurance binder, and reviewing the Investment-Grade Energy Audit, sends out an Invitation to Bid to five certified ESCOs, containing the following information:

The “not to exceed” Total Installed Cost (TIC) of approved performance contracting work: $2,000,000

The allowable ESCO gross margin: 20%

Minimum expected volumetric change: a reduction of 100,000 MWh

The length of the Option: 3 years

The length of the overall PC agreement: 6 years

The threshold IRR=15%

Energy rate “floor”=$50/MWh

Prior to sending out this Invitation to Bid, the customer obtained a Volatility Insurance Binder to hedge 1,000,000 MWh of electricity from going down for a six-year period, at a strike price of $50/MWh. The estimated total cost of this insurance is $50,000 (it is inexpensive, since almost every customer is trying to hedge their energy costs from going up).

$$\begin{matrix}{σ}_{XExist} \pm {σ}_{XNew} = \frac{[ CR ] \times TIC}{{[ {Volume}_{energy} ]}_{Exist - New} \times {Rate}_{energy}} \\ = \frac{.26424 \times \$2 , 000 , 000}{100 , 000 MWh \times \$ 50 / MWh} \\ = 0.1056\end{matrix}$$

CV=σ_{Xexist}±σ_{XNew}×\sqrt{T}=0.1056×\sqrt{3}=0.183 and NPV_{q}=1

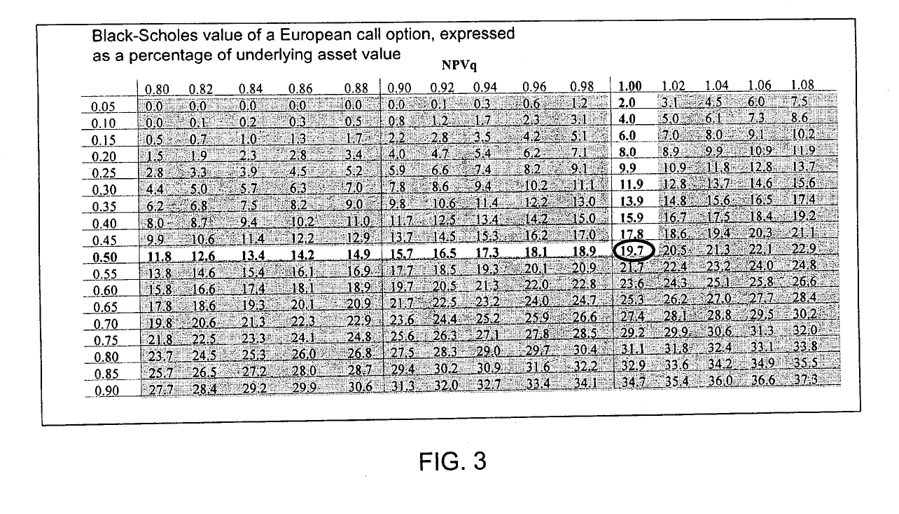

From these values, the minimum Option factor is determined to be 7.2%, which is taken from a European Black-Scholes table, such as the table shown in FIG. 3. The value of an American Option is higher. Of course, as one of ordinary skill in the art would appreciate, any other similar pricing model could be used in the present invention.

The minimum value of the Hunting License Option to each of the ESCOs is then:

$2,000,000×20% gross margin×7.2%=$28,800

All of the bidders believe that the IRR threshold is readily achievable. Where they differ is with respect to the upside potential volatility (σ_{XNew}) of the energy asset upgrade opportunities. Based upon his historical data, the winning bidder believed that he could double the intrinsic volatility within the subject facilities. Thus, his cumulative volatility (CV)=0.366, yielding an Option Factor of 14.0%. Thus, his bid was $56,000.

The net proceeds to the customer are $56,000 less $50,000 for insurance=$6,000.

Although the present invention has largely been described in the context of what is known as Demand-Side ESCOs (involved with the reduction of energy consumption), the invention is also applicable to Supply-Side ESCOs (involved with “creation” of energy, via the energy extraction process). As one of ordinary skill in the art would appreciate, in these supply-side applications of the present invention, the same methodology as the demand-side would be employed, but with a focus on extraction elements, as opposed to consumption elements. For example, the real energy assets discussed above would include potentially extracted energy, such as unharvested fossil fuels. Similarly, the energy asset infrastructure discussed above would include potential energy resources, such as exploration fields and related equipment. Likewise, the intrinsic and extrinsic volatilities would include extraction elements that are affected by changes within and outside of a facility, respectively. The following example (Example 1C) illustrates this alternative supply-side implementation of the present invention.

Example 1C:

The Federal Government, after completion of an Environmental Impact of a Coal-Bed Methane (CBM) field, sends out an Invitation to Bid to interested Energy Producers (supply-side ESCOs), containing the following information:

The expected methane yield is 4.8 billion cubic feet (BCF) per year, based upon an estimated CBM 150 wells.

The useful life of the CBM field and length of the Option period is 10 years.

Each Energy Producer has the minimum same financial parameters, as follows:

Total Installed Cost (TIC) of each CBM well is $300,000

The threshold IRR (where the NPV is 0)=15%

The average cost of methane for the next 10 years is estimated to be $3.00 per thousand cubic feet

$${σ}_{XExist} \pm {σ}_{XNew} = \frac{[ CR ] \times TIC}{{[ {Volume}_{energy} ]}_{Exist - New} \times {Rate}_{energy}}$$

σ_{XExist} and [Volume_{energy}]_{Exist}=0

$${σ}_{XNew} = \frac{.19925 \times \$300 , 000 \times 150 wells}{4.8 BCF / yr \times \$3000 , 000 / BCF \times 10 yrs} = 0.0623$$

CV=σ_{XNew}×\sqrt{T}=0.0623×\sqrt{10}=0.197 and NPV_{q}=1

From these values, the minimum Option factor is determined to be approximately 8%, which is taken from a European Black-Scholes table, such as the table shown in FIG. 3. The value of an American Option is higher. Of course, as one of ordinary skill in the art would appreciate, any other similar pricing model could be used in the present invention.

Thus, the minimum value of the exclusive right to explore the CBM field is approximately 8% of the ESCO's anticipated profit.

With the above examples in mind, the value of the Hunting License for a specific PC project is affected by the aforementioned elements, as follows:

The larger the amount of the Total Installed Cost (TIC) work—the more valuable the Option;

The larger the allowable ESCO gross margin—the more valuable the Option;

The longer the Option period (T)—the more valuable the Option;

The higher the minimum Internal Rate of Return (IRR) threshold—the less valuable the Option;

No extrinsic volatility downside creates a more valuable Option; and

The higher the intrinsic upside volatilities (σₓ)—the more valuable the Option.

In summary, the Hunting License Option will always have some value, unless the confidence level that the stipulated minimum IRR can be achieved diminishes to the point that it becomes worthless.

In an alternative embodiment of the present invention, as more data becomes available for different types of customers, an insurance-like actuarial table approach is utilized to determine the above-referenced probability and variance determinations.

As mentioned above, in an embodiment of the present invention, a component of the Hunting License Option is Volatility Insurance, which “fixes” the values of all extrinsic volatilities and specifically provides a “floor” to ensure against energy rates going down. The term of the Volatility Insurance also establishes an outer limit for the length of the Hunting License Option: the higher the extrinsic volatilities, the more costly the Volatility Insurance, and thus, the shorter the term of the Option. This relationship is especially meaningful for many countries outside the U.S.

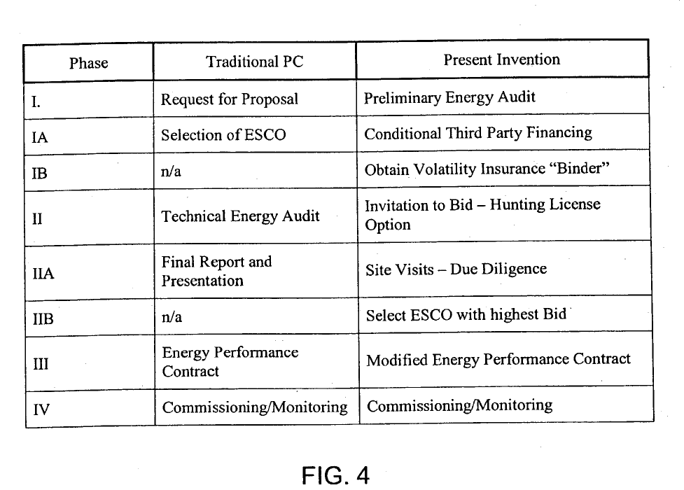

The table shown in FIG. 4 compares traditional performance contracting to the present invention, according to an embodiment of the present invention. With this comparison in mind, the present invention provides one or more of the following benefits:

Increases the “yield” (e.g., from extracted energy or energy savings) from PC projects by harvesting their unrealized potential opportunities.

Creates a scalable, cost-effective method of quantifying future PC work as risk elements become actuarially applied.

Enables PC work to be successfully performed in countries with high volatilities

Particularly suitable for application in Public Works projects due to the very long term, elimination of the Third Party Financier, and generation of cash flow from the Option.

Encourages the application of leading-edge energy extraction and energy consumption reduction technologies

Insures against ESCO losses due to adverse future changes of energy rates.

In addition, in comparison to the traditional performance contracting, the present invention provides one or more of the following novel features:

Applying Real Options, a subset of financial derivatives, to performance contracting which potentially increase yield from energy extraction or energy savings

Creation of the Hunting License Option for use in performance contracting

Creation of Volatility Insurance for use in performance contracting

Creation of the terms “intrinsic” and “extrinsic” volatilities

Creation of a foundation to quantify future intrinsic volatilities through insurance-like actuarial tables

Creation of a process to generate cash-flow (via the Hunting License Option) and to hedge adverse energy rate volatility (via Volatility Insurance)

The present invention offers significant relative value. ESCOs now operate in many countries throughout the world. In those countries with high extrinsic volatility, ESCOs are very conservative with respect to guaranteeing energy extraction and energy savings—the risks are simply too high.

Yet, energy asset infrastructures continue to age, become less efficient, and therefore consume more energy. Capital renewal of energy assets is, in many countries, almost non-existent. Concurrently, power generation resources are strained in many parts of the world, resulting in unpredictable power quality and uptime, as well as volatile costs.

Prior to the present invention, there was no process to harness the potential value within the inherent uncertainty that is a part of every long-term performance contract. Thus, the use of the Hunting License Option, especially when combined with Volatility Insurance, can “Jumpstart” performance contracting in countries presently considered too “risky” (e.g., the U.S.), as well as increase the yield from energy extraction and energy savings in those countries.

Currently, performance contracting is a $30 billion industry in the U.S. alone. Accordingly, it would not be unreasonable to estimate that if the methodology of the present invention becomes widely adopted, it could greatly expand the amount of performance contracting work performed by 5-10% per year, as well as the energy-savings yield by 3-5% domestically and 10%-15% internationally.

Although the embodiments described above illustrate the present invention in the context of performance contracting, and specifically energy performance contracting, one of ordinary skill in the art would appreciate that the present invention is useful for many other business situations that involve similar characteristics. These characteristics include one or more of the following:

Limited current information;

Long term agreements;

Threshold financial hurdles;

Guaranteed savings; and

High level of future uncertainty—some which are “controllable” and others that are “hedgeable.”

Thus, for example, in addition to performance contracting, the present invention could be applied to an exclusive right to act as agent to make acquisitions (e.g., businesses and income-producing real estate) on behalf of a customer. The invention could also be applied to an exclusive right to explore for resources, such as oil, gas, and gold, on behalf of a landowner (e.g., as described above in Example 1B). The invention would also apply to the currently unexploited opportunity of producers' vendors applying new technologies on a performance-based basis to improve financial yields. As another example, the invention could be applied to an exclusive right to act as an investment adviser. For this reason, and notwithstanding the particular benefits associated with using the present invention to increase yield from performance contracts, the system and method described herein should be considered broadly useful for business situations having some or all of the characteristics described above.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed is:

1. A method for increasing yield from a performance contract having intrinsic volatility, wherein the intrinsic volatility involves elements affected by changes that are controllable, the method comprising:
converting a future upside potential value of the intrinsic volatility into a current monetary benefit; and
using the current monetary benefit to hedge against future extrinsic volatility that could diminish the future upside potential value, wherein the future extrinsic volatility involves risks that are hedgeable.

2. The method of claim 1, further comprising obtaining volatility insurance that, during the performance contract, hedges against changes in the future extrinsic volatility.

3. The method of claim 2, wherein the performance contract is an energy performance contract, and wherein the volatility insurance hedges against a stipulated energy rate going down, interest rates going up, and currency rate volatility.

4. The method of claim 1, wherein the performance contract is an energy performance contract, and the intrinsic volatility includes at least one of energy volume risk, asset performance risk, and energy baseline uncertainty risk.

5. The method of claim 1, wherein the performance contract is an energy performance contract, and the future extrinsic volatility includes at least one of energy risk rate, labor cost risk, interest rate risk, and currency risk.

6. The method of claim 1, wherein the performance contract is an energy performance contract, and wherein converting the future upside potential value of the intrinsic volatility into the current monetary benefit comprises calculating an option,
wherein the option=total installed cost (TIC)×gross margin×option factor,
wherein the option factor is determined from a cumulative volatility (CV) and a net present value (NPV_{q}),
wherein NPV_{q}=1,
wherein CV=σ_{Xexist}±σ_{XNew}×\sqrt{T},
wherein
$${σ}_{XExist} \pm {σ}_{XNew} = \frac{[ CR ] \times TIC}{{[ {Volume}_{energy} ]}_{Exist - New} \times {Rate}_{energy}}$$
wherein CR=capital recovery factor,
wherein T=length of the option,
wherein [Volume_{energy}]_{Exist-New}=minimum expected volumetric change, and
wherein Rate_{energy}=energy rate floor.

7. The method of claim 6, wherein the option factor is taken from a European Black-Scholes table based on the CV and the NPV_{q}.

8. The method of claim 6, wherein the CV is adjusted based on actuarial tables.

9. The method of claim 1, wherein the intrinsic volatility and the future extrinsic volatility relate to one of energy consumption reduction and energy extraction.

10. The method of claim 1, wherein the controllable changes occur within a facility related to the performance contract, and wherein the hedgeable risks exist outside of the facility.

11. A method for increasing yield from a performance contract for a project, the method comprising:
establishing performance contract requirements that define a not-to-exceed total installed cost (TIC), a minimum threshold internal rate of return (IRR), and an option period;
establishing a total return for the project;
distributing to bidders an invitation to bid for an option, wherein the invitation conveys the performance contract requirements and the total return;
receiving bids for the option from the bidders, wherein the bids are based on the total return, on a probability of achieving the IRR for the TIC within the option period, and on an estimated intrinsic volatility, and wherein the estimated intrinsic volatility involves elements affected by changes that are controllable; and
selecting the highest bid for the option.

12. The method of claim 11, wherein the performance contract is an energy performance contract, and the intrinsic volatility includes at least one of energy volume risk, asset performance risk, and energy baseline uncertainty risk.

13. The method of claim 11, further comprising obtaining volatility insurance that, during the performance contract, hedges against changes in future extrinsic volatility, wherein the future extrinsic volatility involves risks that are hedgeable.

14. The method of claim 13, wherein the performance contract is an energy performance contract, and the future extrinsic volatility includes at least one of energy risk rate, labor cost risk, interest rate risk, and currency risk.

15. The method of claim 13, wherein the intrinsic volatility and the future extrinsic volatility relate to one of energy consumption reduction and energy extraction.

16. The method of claim 11, wherein the option is exclusive to a winning bidder until expiration of the option period, and wherein portions of the project that meet the IRR must be approved until the TIC is reached.

17. The method of claim 11, wherein the performance contract is an energy performance contract,
wherein the option=(TIC)×gross margin×option factor,
wherein the option factor is determined from a cumulative volatility (CV) and a net present value (NPV_{q}),
wherein NPV_{q}=1,
wherein CV=σ_{Xexist}±σ_{XNew}×\sqrt{T},
wherein
$${σ}_{XExist} \pm {σ}_{XNew} = \frac{[ CR ] \times TIC}{{[ {Volume}_{energy} ]}_{Exist - New} \times {Rate}_{energy}}$$
wherein CR=capital recovery factor,
wherein T=length of the option,
wherein [Volume_{energy}]_{Exist-New}=minimum expected volumetric change, and
wherein Rate_{energy}=energy rate floor.

18. A method for increasing yield from a performance contract for a project, the method comprising:
receiving an invitation to bid for an option, wherein the invitation defines a not-to-exceed total installed cost (TIC), a minimum threshold internal rate of return (IRR), an option period, and a total return for the project;
assessing a probability of achieving the IRR for the TIC within the option period;
estimating an intrinsic volatility, wherein the intrinsic volatility involves elements affected by changes that are controllable;
calculating a highest value of the option based on the total return, the probability, and the estimated intrinsic volatility; and
submitting the highest value as a bid in response to the invitation.

19. The method of claim 18, wherein the performance contract is an energy performance contract, and wherein calculating the highest value of the option comprises calculating TIC×gross margin×option factor,
wherein the option factor is determined from a cumulative volatility (CV) and a net present value (NPV_{q}),
wherein NPV_{q}=1,
wherein CV=σ_{Xexist}±σ_{XNew}×\sqrt{T},
wherein
$${σ}_{XExist} \pm {σ}_{XNew} = \frac{[ CR ] \times TIC}{{[ {Volume}_{energy} ]}_{Exist - New} \times {Rate}_{energy}}$$
wherein CR=capital recovery factor,
wherein T=length of the option,
wherein [Volume_{energy}]_{Exist-New}=minimum expected volumetric change, and
wherein Rate_{energy}=energy rate floor.

20. A method for increasing yield from a performance contract for a project, the method comprising:
establishing performance contract requirements, wherein the performance contract requirements define a not-to-exceed total installed cost (TIC), a minimum threshold internal rate of return (IRR), and an option period;
establishing a total return for the project;
distributing to bidders an invitation to bid for an option, wherein the invitation conveys the performance contract requirements and the total return;
for each bidder,
assessing a probability of achieving the IRR for the TIC within the option period,
estimating an intrinsic volatility, wherein the intrinsic volatility involves elements affected by changes that are controllable,
calculating a value of the option based on the total return, the probability, and the estimated intrinsic volatility, and
submitting the value as a bid in response to the invitation; and
selecting a bidder with the highest bid value.

21. The method of claim 20, further comprising obtaining volatility insurance that, during the performance contract, hedges against changes in future extrinsic volatility, wherein the future extrinsic volatility involves risks that are hedgeable.

22. The method of claim 21, wherein the intrinsic volatility and the future extrinsic volatility relate to one of energy consumption reduction and energy extraction.

23. The method of claim 20, wherein the performance contract is an energy performance contract, and wherein calculating the value of the option comprises calculating TIC×gross margin×option factor,
wherein the option factor is determined from a cumulative volatility (CV) and a net present value (NPV_{q}),
wherein NPV_{q}=1,
wherein CV=σ_{Xexist}±σ_{XNew}×\sqrt{T},
wherein
$${σ}_{XExist} \pm {σ}_{XNew} = \frac{[ CR ] \times TIC}{{[ {Volume}_{energy} ]}_{Exist - New} \times {Rate}_{energy}}$$
wherein CR=capital recovery factor,
wherein T=length of the option,
wherein [Volume_{energy}]_{Exist-New}=minimum expected volumetric change, and
wherein Rate_{energy}=energy rate floor.

24. A system for increasing yield from an energy performance contract for a project, the system comprising:
an owner of the project;
a third party financier that lends money to the owner to pay for the project;
an insurance provider that provides the owner with volatility insurance that, during the performance contract, hedges against changes in future extrinsic volatility, wherein the future extrinsic volatility involves risks that are hedgeable; and
an energy service company that pays the owner for an option, wherein the option=a total installed cost (TIC)×a gross margin×an option factor.

25. The system of claim 24, wherein the option factor is determined from a cumulative volatility (CV) and a net present value (NPV_{q}),
wherein NPV_{q}=1,
wherein CV=σ_{Xexist}±σ_{XNew}×\sqrt{T},
wherein
$${σ}_{XExist} \pm {σ}_{XNew} = \frac{[ CR ] \times TIC}{{[ {Volume}_{energy} ]}_{Exist - New} \times {Rate}_{energy}}$$
wherein CR=capital recovery factor,
wherein T=length of the option,
wherein [Volume_{energy}]_{Exist-New}=minimum expected volumetric change, and
wherein Rate_{energy}=energy rate floor.

26. The system of claim 24, wherein the hedgeable risks comprise a stipulated energy rate going down, interest rates going up, and currency rate volatility.

27. The system of claim 24, wherein a facility is associated with the performance contract, and wherein the hedgeable risks exist outside of the facility.
